(19) United States
(12) Patent Application Publication
(10) Pub. No.: US 2026/0090392 A1
(43) Pub. Date: Mar. 26, 2026

(54) Chip-to-Chip High Speed Connection Interface Tuning Structure

(71) Applicant: Tenstorrent USA, Inc., Austin, TX (US)

(72) Inventor: Fei Guo, Ottawa (CA)

(21) Appl. No.: 18/895,348

(22) Filed: Sep. 24, 2024

(51) Int. Cl. H01L 23/66; H01L 23/00; H01L 23/538; H01L 25/065

(52) U.S. Cl. CPC H10W 44/20; H10W 70/611; H10W 70/65; H10W 90/00; H10W 44/206; H10W 90/724

(57) ABSTRACT

Methods and systems related to chip-to-chip electrical connection interfaces are disclosed. The electrical connections can be formed between chiplets, chip-scale packages, or unpackaged die. The electrical connection can serve as a physical connection to support various interface protocols such as the Bunch of Wires (BoW) or Universal Chiplet Interconnect Express (UCIe) protocols. An electrical connection interface comprises a first die connection for a first die, a first tuning block, a first escape region connection coupling the first die connection to the first tuning block, a second die connection for a second die, a second tuning block, a second escape region connection coupling the second die connection to the second tuning block, and a main trace coupling the first tuning block to the second tuning block.

### BACKGROUND

The problem of increasing I/O pad capacitance, driven by Electrostatic Discharge (ESD) protection circuits, I/O drivers, and the I/O pad itself, poses a significant challenge for high-speed die-to-die interconnects. As capacitance increases, it can degrade the signal integrity by slowing down the rise and fall times of high-speed signals, leading to increased latency and reduced bandwidth. High capacitance also contributes to signal reflections and crosstalk, further compromising communication between dice. This issue is particularly critical as modern interconnects demand faster data rates and tighter timing margins, where even small amounts of added capacitance can cause noticeable performance degradation. Moreover, while ESD protection is essential to safeguard against damaging voltage spikes, its associated capacitance can exacerbate these challenges, creating a trade-off between circuit protection and signal performance.

This problem is becoming even more critical with the increased reliance on die-to-die links in advanced applications, such as chiplet-based designs and die-scale packages. Technologies like BoW (Bunch of Wires) and UCIe (Universal Chiplet Interconnect Express) are emerging as standard protocols to enable efficient communication between dice within the same package. These high-performance interconnects demand extremely low latency and high data throughput, making the impact of I/O pad capacitance more pronounced. As chiplet architectures push the limits of integration density and speed, minimizing signal degradation becomes essential to maintain performance. Excessive capacitance in I/O pads, introduced by ESD protection and I/O drivers, can bottleneck the overall communication bandwidth and negate the benefits of these advanced packaging techniques. This makes optimizing I/O pad designs a top priority in modern semiconductor manufacturing, as it directly influences the viability of chiplet and die-to-die interconnect solutions in high-speed computing applications.

### SUMMARY

This disclosure relates to chip-to-chip high speed connection interfaces. In particular, the disclosure relates to tuning structure for chip-to-chip high speed connection interfaces that contribute to the preservation of signal integrity for signals sent on a chip-to-chip connection in high bandwidth applications. Chip-to-chip connections can be formed by lines of conductive material formed in or on insulative substrates. In specific embodiments, the tuning structures disclosed herein can be formed from the same conductive material used to form the connections.

Chip-to-chip connections can include chip contacts on each chip, such as a bumps or pads, which couple electrical signals to the internals of the chip, a main trace which routes electrical signals across a substrate from the proximity of one chip to another chip, and escape area connections which couple the chip contacts to the main trace. The “escape area” can also be referred to as the “neck area.” The escape area includes a set of escape area connections that couple a set of chip contacts to an external set of chip-to-chip connections. In specific embodiments, the tuning structures can take the form of regions of conductive material that couple the escape area connections to the main trace and that are thicker than the escape area connections. In specific embodiments, the tuning structures can be formed of the same material as, and using the same processing steps as, the main trace, the escape area, or both. As such, the tuning structures can be added to a design with a minimal increase in the cost of the design.

The tuning structures can be shaped to improve the radio frequency characteristics of the chip-to-chip connections by providing impedance matching. The main trace can be accordingly conceptualized as a transmission line, and the tuning structures can introduce impedance matching to minimize loss and crosstalk on the chip-to-chip connections. Analyzing the height and width of a data eye for a signal transmitted on the chip-to-chip connection can be used as a proxy for measuring the performance of the chip-to-chip connection in maintaining signal integrity for signals transmitted using the connection. In specific embodiments, the tuning structures can be sheets of conductive material formed on an insulative substrate and having various top-down shapes. The surface area of the top-down shape can define a capacitance provided by the tuning structure. The conductive material can be the conductive material that is used to form the main trace or the edge region connection. The distance of the path across the surface area from the edge structure to the main trace and the width of that path can define a resistance provided by the tuning structure. In specific embodiments, the tuning structures can be tuning blocks having quadrilateral top-down shapes formed in a sheet on an insulative substrate.

The tuning structure can provide impedance matching through the capacitance introduced between the conductive material of the tuning structure and the insulative material of the substrate and the resistance and inductance introduced by extending the length of the connection to the main trace. In specific embodiments, the size of the tuning structures can be selected to maximize an eye height and an eye width of the chip-to-chip connection. For example, two tuning structures on either side of a chip-to-chip connection can be rectangular and share a height and width. The height and the width can increase an eye height and an eye width of the chip-to-chip connection as compared to the same chip-to-chip connection without the two tuning structures and with the main trace directly coupling the two escape region connections.

In specific embodiments of the invention, tuning a chip-to-chip connection can be conducted through an iterative process, subject to certain constraints as described below, which seeks to minimize RF loss on the chip-to-chip connections. This process can use the data eye height and eye width as two key metrics to maximize while configuring the lengths of the escape area connections, and shape (e.g., the lengths and widths) of the tuning structures.

In specific embodiments of the invention, an electrical connection interface is provided. The electrical connection interface comprises a first die connection for a first die, a first tuning block, a first escape region connection coupling the first die connection to the first tuning block, a second die connection for a second die, a second tuning block, a second escape region connection coupling the second die connection to the second tuning block, and a main trace coupling the first tuning block to the second tuning block.

In specific embodiments of the invention, an electrical connection interface is provided. The electrical connection interface comprises a first die connection for a first die, a first tuning structure, a first escape region connection coupling the first die connection to the first tuning structure, a second die connection for a second die, a second tuning structure, a second escape region connection coupling the second die connection to the second tuning structure, and a main trace coupling the first tuning structure to the second tuning structure, wherein the main trace, the first tuning structure, the second tuning structure are all formed of a single material and using a same processing step.

In specific embodiments of the invention, a method for tuning an electrical connection interface is provided. The method comprises determining a minimum trace width, a minimum gap between a trace and a second trace, and a maximum length for an escape region based at least in part on one or more electrical connection interface design rules; setting a first length range for the escape region of the trace based at least in part on the maximum length for the escape region; setting a first width range for a tuning structure region of the trace based at least in part on the minimum gap; setting a second width range for a main trace region of the trace based at least in part on the minimum trace width and the minimum gap; and optimizing a length of the escape region, a length of the tuning structure region, a width of the main trace region, and a width of the tuning structure region based at least in part on setting the first length range, setting the first width range, and setting the second width range, wherein the optimization maximizes eye height and eye width of a data eye diagram.

### BRIEF DESCRIPTION OF THE DRAWINGS

The accompanying drawings illustrate embodiments of systems, methods, and various other aspects of the disclosure. A person with ordinary skills in the art will appreciate that the illustrated element boundaries (e.g., boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another, and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1 provides an example of a die-to-die channel in accordance with specific embodiments of the inventions disclosed herein.

FIG. 2 provides an example of a set of traces with tuning structures built into each trace in accordance with specific embodiments of the inventions disclosed herein.

FIG. 3 provides an example of one side of a set of die-to-die traces without tuning structures and one side of a set of die-to-die traces with tuning structures in accordance with specific embodiments of the inventions disclosed herein.

FIG. 4 provides an example of an electrical connection interface with tuning structures in accordance with specific embodiments of the inventions disclosed herein.

FIG. 5 provides an example of a graph showing scattering parameters across frequencies for a die-to-die channel without tuned structures and a die-to-die channel with tuned structures in accordance with specific embodiments of the inventions disclosed herein.

FIG. 6 provides an example of a table of a simulation of minimum eye heights and minimum eye widths for various datalines in a system in accordance with specific embodiments of the inventions disclosed herein.

FIG. 7 provides an example of a method for tuning an electrical connection interface in accordance with specific embodiments of the inventions disclosed herein.

### DETAILED DESCRIPTION

Reference will now be made in detail to implementations and embodiments of various aspects and variations of systems and methods described herein. Although several exemplary variations of the systems and methods are described herein, other variations of the systems and methods may include aspects of the systems and methods described herein combined in any suitable manner having combinations of all or some of the aspects described.

Different systems and methods related to electrical connection interfaces are described in detail in this disclosure. The methods and systems disclosed in this section are nonlimiting embodiments of the invention, are provided for explanatory purposes only, and should not be used to constrict the full scope of the invention. It is to be understood that the disclosed embodiments may or may not overlap with each other. Thus, part of one embodiment, or specific embodiments thereof, may or may not fall within the ambit of another, or specific embodiments thereof, and vice versa. Different embodiments from different aspects may be combined or practiced separately. Many different combinations and sub-combinations of the representative embodiments shown within the broad framework of this invention, that may be apparent to those skilled in the art but not explicitly shown or described, should not be construed as precluded.

In specific embodiments, the tuning structures disclosed herein can be used for impedance matching to improve the high frequency performance of a chip-to-chip electrical connection interface to which they are a part. Impedance matching in a high frequency electrical connection interface ensures accurate transmission of information and minimizes signal reflections. A main trace of a chip-to-chip electrical connection will have a characteristic impedance, which is the inherent opposition to the flow of alternating current (AC) at high frequencies in the main trace. To achieve impedance matching, the impedance of the load (in this case the die connection, tuning structure, and escape region connection) must be equal to the characteristic impedance of the main trace. When these impedances are matched, a signal can travel along the main trace and be received without being reflected back toward the source. Reflections occur if there is a mismatch, resulting in standing waves and signal loss.

In general, impedance matching can be achieved using various methods, such as using matching networks (e.g., transformers, stubs, or L-networks) or adjusting the physical length and properties of the transmission line (main trace in this application). However, in specific applications in accordance with this disclosure, the length and properties of the main trace are fixed by the layout of the chips that are being connected and a desire to minimize the overall impedance and capacitance of the trace. As such, impedance matching can instead be achieved, in specific embodiments of the invention, by altering the impedance of the load via the sizing of the escape region connection and the tuning structures disclosed herein.

The design rules for a given chip-to-chip connection process pose a maximum length on the escape area connections because they are generally thinner than the main trace. Escape area connections may have length and thickness requirements (e.g., minimums or maximums) based on performance requirements, manufacturing capabilities, standards, or other factors. Connections can be formed on substrates in the form of organic interposers, glass interposers, silicon interposers, laminate interposers, embedded bridges, overlay bridges, inter-package substrates, printed circuit boards, etc.

Specific embodiments as described herein may be beneficial to chip-to-chip interfaces, die-to-die interfaces, chiplet-to-chiplet interfaces, and other two chip-scale packages. In specific embodiments, the chips can be in the same package. Additionally, specific embodiments of the inventions disclosed herein may be used for a variety of protocols including bunch of wires (BoW) and universal chiplet interconnect express (UCIe). Although generally discussed in the context of compensating for I/O pad capacitance, tuning structures may also be applicable and beneficial in other types of high speed interfaces. In different high speed applications, the tuning structures may be optimized for different bandwidth targets.

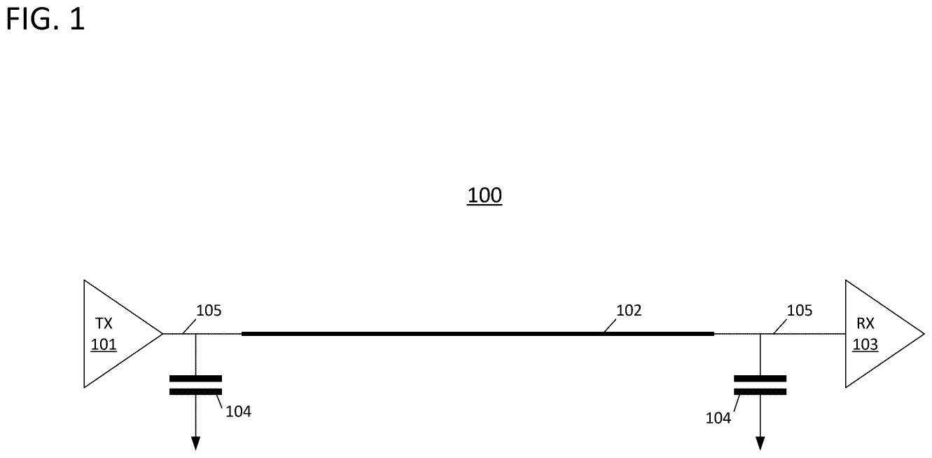

FIG. 1 illustrates an example of die-to-die channel 100 in accordance with specific embodiments of the invention. Channel 100 may be part of an I/O pad and may include transmitter 101, passive channel 102, receiver 103, I/O capacitances 104 (represented as capacitors), and chip contact regions 105.

Many factors may increase I/O pad capacitance including electrostatic discharge (ESD) protection circuits, I/O drivers, and the I/O pad itself. The capacitance of the I/O pad may become a limiting factor in channel bandwidth for die-to-die links such as BOW and UCIe. The die-to-die links may be power-constrained and area-constrained. Accordingly, using various equalizers in the analog front end (AFE) such as a transmitter feed-forward equalizer (TX FFE) or a receiver decision feedback equalizer (RX DFE) to improve the channel signal integrity performance may not be desirable. In many situations, I/O pad capacitance cannot be avoided and may be around a few hundred femtofarads (fF). For high speed channels, the I/O pad capacitance may be a limiting factor on the channel bandwidth.

Passive channel 102 may include the main trace region and other trace regions. In a typical passive channel, the trace may be routed as a uniform transmission line with required impedance. In chip contact regions 105 of both ends of the channel, a small section of narrower trace may be implemented for manufacturing purposes. In specific embodiments of the inventions as described herein, channel 100 may have varied geometries. For example, channel 100 (e.g., passive channel 102 and bump regions 105) may include a combination of narrow trace regions, wide regions, and regions with thicknesses in between.

A wider portion of channel 100 may be referred to as a tuning structure or tuning block. There may be two tuning structures on channel 100, a tuning structure being associated with each end of channel 100 (e.g., between a chip contact region 105 and a main trace region). The dimensions (e.g., length, width, shape) of the tuning structures may be optimized for impedance matching, minimizing return loss, minimizing insertion loss, maximizing eye height of a data eye diagram, maximizing eye width of a data eye diagram, or a combination thereof. In specific embodiments, the tuning structures can be sheets of conductive material formed on an insulative substrate and having various top-down shapes. The surface area of the top-down shape can define a capacitance provided by the tuning structure. A tuning structure may improve the bandwidth of channel 100. For example, the tuning structure may improve the bandwidth to be above the Nyquist frequency of the targeted data rate of channel 100.

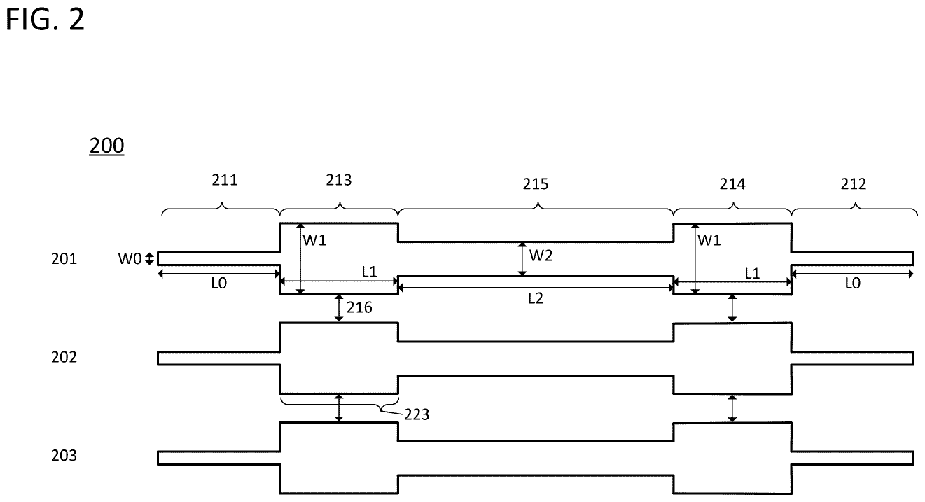

FIG. 2 illustrates an example of a set of traces 200 with tuning structures built into each trace 201, 202, and 203 in accordance with specific embodiments of the inventions as disclosed herein. Set of traces 200 may be part of an I/O pad and each trace 201, 202, and 203 may be part of or include a passive channel (for example passive channel 102 of FIG. 1) and chip contact regions (e.g., chip contact regions 105 of FIG. 1). Trace 201 may include regions 211 through 215. Trace 202 and 203 may be similar to trace 201.

Region 211 and region 212 of trace 201 may each be narrow trace regions and may each have a first width W0 and a first length L0. Width W0 may be set according to manufacturing capabilities, impedance matching, electrical connection interface design rules, or other design considerations. Region 211 and region 212 may be referred to as neck regions, neck region connections, escape regions, or escape region connections.

Region 213 and region 214 of trace 201 may each be wider regions (e.g., steps) and may each have a second width W1 and a second length L1. Width W1 may be wider than width W0. Width W1 may be set according to manufacturing capabilities, impedance matching, electrical connection interface design rules, or other design considerations. Regions 213 and 214 may be referred to as tuning blocks or tuning structures. In specific embodiments, the regions 213 and 214 can be sheets of conductive material formed on an insulative substrate and having various top-down shapes. The surface area of the top-down shape can define a capacitance provided by regions 213 and 214. In specific embodiments, the distance (e.g., L1) of the path across the surface area from the edge structure to the main trace and the width (e.g., W1) of that path can define a resistance provided by regions 213 and 214. In specific embodiments, regions 213 and 214 can be tuning blocks having quadrilateral top-down shapes formed in a sheet on an insulative substrate.

Region 215 of trace 201 may be a main trace region and may have a third width W2 and a third length L2. Width W2 may be wider than width W0 but narrower than width W1. Width W2 may be set according to manufacturing capabilities, impedance matching, electrical connection interface design rules, or other design considerations. In specific embodiments, the length L2 and other properties of region 215 are fixed by the layout of the chips that are being connected and a desire to minimize the overall impedance and capacitance of trace 201. As such, impedance matching may be achieved by altering the impedance of the load via the sizing of regions 211 through 214. In specific embodiments, the lengths L0 and L1 of regions 211, 212, 213, and 214, and the widths W0, W1, and W2 of regions 211, 212, 213, 214, and 215 may be adjusted to minimize signal reflection (e.g., along trace 201, along region 215). In specific embodiments, the widths W0 of regions 211 and 212 are a minimum trace width (e.g., as set by an electrical connection interface design rule).

Adjusting the dimensions of regions 211 through 215 may take into account many factors. The dimensions (e.g., length, width, shape) of regions 211 through 215 may be optimized for impedance matching, minimizing return loss, minimizing insertion loss, maximizing eye height of a data eye diagram, maximizing eye width of a data eye diagram, or a combination thereof. The optimization of regions 211 through 215 may take into account the gap 216 (e.g., space) between region 213 of trace 201 and region 223 of trace 202. Gap 216 may be equal to or greater than a minimum gap between traces according to electrical connection interface design rules. Gap 216 may contribute to setting a maximum width W1 of region 213. The optimization of regions 211 through 215 may take into account a minimum trace width, maximum lengths for region 211 and 212, and a possibly fixed length of trace 201 as a whole. Various electrical connection interface design rules and variables (e.g., specific to the system) may also be considered. Regions 211 and 212 may or may not be symmetric. Regions 213 and 214 may or may not be symmetric. In specific embodiments, symmetry is preferred. In specific embodiments, one or more regions 211 through 215 may be short or nonexistent.

Regions 213 and 214 may improve the bandwidth of trace 201. For example, regions 213 and 214 may improve the bandwidth of trace 201 to be above the Nyquist frequency of the targeted data rate of trace 201. Regions 213 and 214 may also reduce crosstalk, reduce loss, and reduce signal reflections of trace 201. Additionally, similar regions on traces 202 and 203 may make similar improvements for set of traces 200.

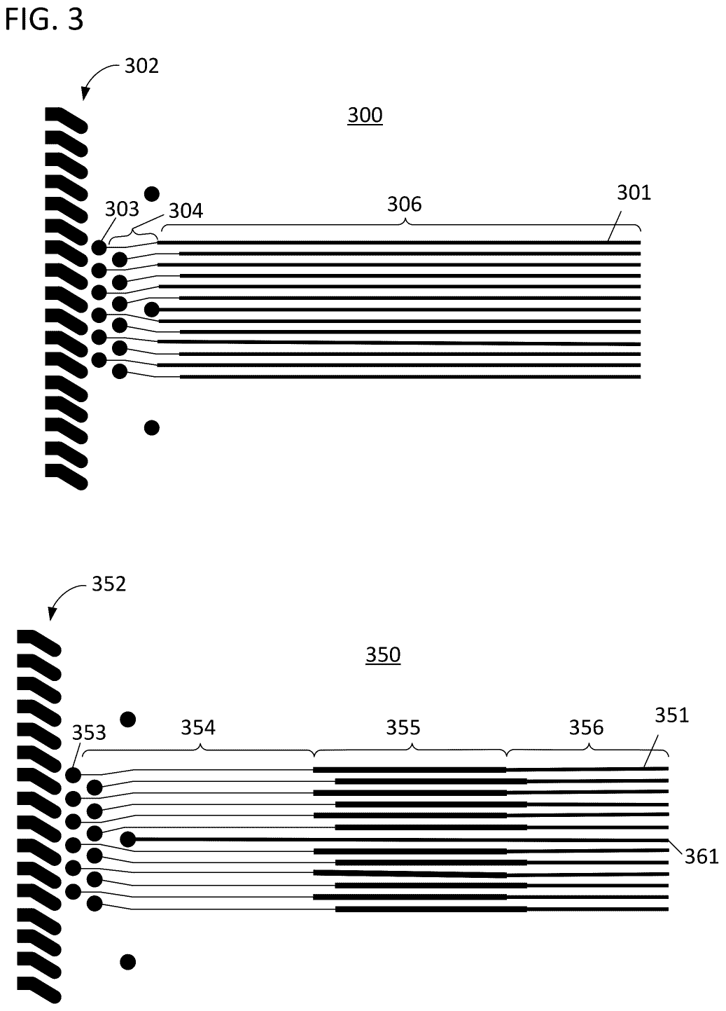

FIG. 3 illustrates one side of a set of die-to-die traces 300 and one side of a set of die-to-die traces 350 with tuning structures 355. Trace 301 may include contact 303 (e.g., a bump such as a solder bump or a pad such as a via pad on a particular signal layer), trace connection 304, and main trace 306. Set of traces 300 connect die 302 to another die (not shown). Trace 351 may include contact 353 (e.g., a bump such as a solder bump or a pad such as a via pad on a particular signal layer), trace connection 354, tuning structure 355, and main trace 356. Set of traces 350 connect die 352 to another die (not shown). Trace connection 354 may be similar to region 211 of trace 201 of FIG. 2. Trace connection 354 may be an escape region or escape region connection. Tuning structure 355 may be similar to region 213 of trace 201 of FIG. 2. Tuning structure 355 may be a tuning block. Main trace 356 may be similar to region 215 of FIG. 2. Contact 353 may be referred to as a die connection. In specific embodiments, VSS vias may be connected at different locations.

Set of traces 300 and set of traces 350 may each receive and transmit high speed signals. However, set of traces 350 may have improved properties compared to set of traces 300 such as improved impedance matching, larger bandwidth, less signal reflection, less return loss, and less insertion loss.

Tuning structure 355 may improve the bandwidth of trace 351. A matching tuning structure may be at the other end of trace 351 (e.g., a receiving or transmitting end). Trace connection 354, tuning structure 355, and main trace 356 may have optimized lengths and thicknesses. As part of the optimization, in specific embodiments, trace connection 354, tuning structure 355, main trace 356, or a combination may be short or nonexistent. In specific embodiments, a trace (e.g., channel) may not have any trace connection 354; instead, tuning structure 355 may connect directly to contact 353. In specific embodiments, a trace may not have any trace connection 354 or tuning structure 355; instead, main trace 356 may connect directly to contact 353. For example, trace 361 of set of traces 350 has a main trace connected directly to a contact. Other traces of set of traces 350 have three distinct regions, although the widths and lengths of respective trace connections, tuning structures, and main traces may vary between traces.

Trace connection 354, tuning structure 355, and main trace 356 may each have variable widths or thicknesses. In specific embodiments, not all dimensions are variable. For example, the length and other properties of main trace 356 or of trace 351 as a whole (e.g., including trace connection 354, tuning structure 355, and main trace 356) may be fixed by the layout of the chips that are being connected and a desire to minimize the overall impedance and capacitance of trace 351. In specific embodiments, the width of trace connection 354 is a minimum trace width (e.g., as set by an electrical connection interface design rule).

In specific embodiments, the lengths and widths of trace connection 354, tuning structure 355, and main trace 356 may be adjusted or optimized for impedance matching, to minimize signal reflection, minimize return loss, minimize insertion loss, maximize eye height of a data eye diagram, maximize eye width of a data eye diagram, or a combination thereof. Adjusting the dimensions of trace connection 354, tuning structure 355, and main trace 356 may take into account many factors, for example a minimum gap between traces, a minimum width of trace 351, a maximum lengths for trace connection 354, and a possibly fixed length of trace 351 as a whole. Various electrical connection interface design rules and variables (e.g., specific to the system) may also be considered.

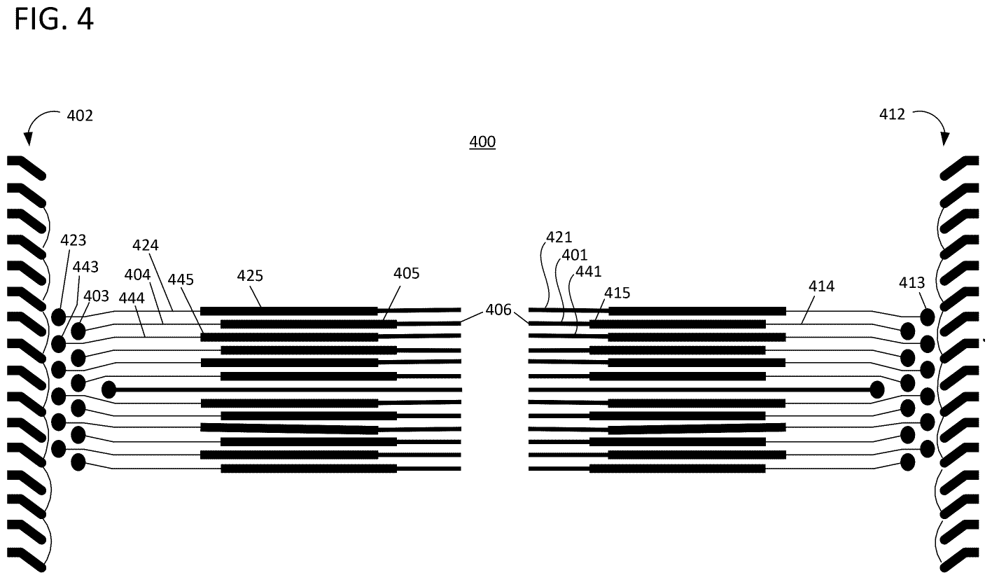

FIG. 4 illustrates electrical connection interface 400 with tuning structures 405. Interface 400 includes thirteen traces, among them trace 421 (top trace), trace 401 (second trace from the top), and trace 441 (third trace from the top) connecting die 402 and die 412. Trace 401 may include die connection 403, escape region connection 404, tuning structure 405, main trace 406, tuning structure 415, escape region connection 414, and die connection 413. Signals may travel from die 402 to die 412 or from die 412 to die 402. Trace 401 may be similar to trace 351, die connections 403 and 413 may be similar to contact 353, escape region connections 404 and 414 may be similar to trace connection 354, tuning structures 405 and 415 may be similar to tuning structure 355, and main trace 406 may be similar to main trace 356 of FIG. 3. In specific embodiments, VSS vias may be connected at different locations. In specific embodiments, a tuning structure may also be referred to as a tuning block, especially if the tuning structure has a quadrilateral top-down shape. An escape region connection may also be referred to as an escape region of a trace. In specific embodiments, some properties of trace 401 are fixed (e.g., by the layout of the chips that are being connected and a desire to minimize the overall impedance and capacitance of trace 401). Main trace 406 may be long such that a discontinuity of main trace 406 (and of other main traces in interface 400) is shown in FIG. 4.

Interface 400 may or may not be symmetric. Escape region connection 404 may or may not have the same dimensions as escape region connection 414. Tuning structure 405 may or may not have the same dimensions as tuning structure 415. In specific embodiments, symmetry may be preferred. In specific embodiments, an impedance of tuning structure 405 and escape region connection 404 match an impedance of main trace 406. In specific embodiments, an impedance of die connection 403 tuning structure 405 and escape region connection 404 match an impedance of main trace 406.

Escape region connection 404 may connect or couple die 402 to tuning structure 405. Escape region connection 414 may connect or couple die 412 to tuning structure 415. Main trace 406 may couple tuning structure 405 to tuning structure 415. In specific embodiments, tuning structure 405 and tuning structure 415 may be wider than main trace 406. Escape region connection 404 may be narrower than main trace 406. In specific embodiments, tuning structure 405, tuning structure 415, main trace 406, and escape region connection 404 may be formed by the single material. In specific embodiments, escape region connection 414 may also be formed of that single material.

Tuning structure 405 and tuning structure 415 may have the same (e.g., share) width and length. The width and length may increase (e.g., optimize) an eye height and an eye width of interface 400 as compared to an electrical connection interface (e.g., a trace) that does not have tuning structure 405 or tuning structure 415, where a main trace would directly couple a first escape region connection to a second escape region connection.

In specific embodiments, escape region connection 404 and escape region connection 414 may be longer than one millimeter and tuning structure 405 and tuning structure 415 may be thicker than 30 microns and longer than one millimeter. In specific embodiments, main trace 406, escape region connection 404, and escape region connection 414 may be narrower than one millimeter. Escape region connection 404 may be greater than or equal to a minimum width as set by an electrical connection interface design rule. Escape region connection 404 may have a length less than a maximum allowed by the electrical connection interface design rule.

In specific embodiments, main trace 406, tuning structure 405, and tuning structure 415 are all formed of the single material and using the same processing step. In specific embodiments, main trace 406, escape region connections 404 and 414, tuning structures 405 and 415, are all formed by a wire material on an insulative substrate. In specific embodiments, main trace 406, escape region connections 404 and 414, tuning structures 405 and 415, are all formed by a metal trace material on an insulative substrate. Die connection 403 and die connection 413 may be one of solder bumps or die pads.

Interface 400 may include traces 421 and 441 in addition to trace 401, as well as other traces. Trace 401 may be located between trace 421 and trace 441 such that trace 421 and trace 441 form a pair of traces adjacent to trace 441. Trace 421 may include die connection 423, escape region connection 424, and tuning structure 425. Trace 441 may include die connection 443, escape region connection 444, and tuning structure 445. Traces 401, 421, and 441 may share similar geometries, have different geometries, or a combination thereof.

Interface 400 may include a pair of adjacent or additional die connections for die 402, such as die connection 423 and die connection 443. That is, die connection 403 may be located in between or adjacent to both die connections 423 and 443. Interface 400 may include a pair of adjacent tuning structures or blocks connected to the pair of adjacent die connections. That is, tuning structure 425 may be coupled to die connection 423 (e.g., via escape region connection 424) and tuning structure 445 may be coupled to die connection 443 (e.g., via escape region connection 444). Tuning structure 405 may have a maximum possible width set by a required minimum spacing between tuning structure 405 and adjacent tuning structures 425 and 445 as set by the electrical connection interface design rule.

Because of tuning structure 405, trace 401 may have improved properties compared to a trace without tuning structures. For example, trace 401 may have improved impedance matching, larger bandwidth, less signal reflection, less return loss, less insertion loss, improved crosstalk, improved data eye height, and improved data eye width. Trace 401 may achieve these benefits with minimal increase to the cost of the design, as tuning structure 405 may be formed of the single material and using the same processing steps as main trace 406 and escape region connections 404 and 414.

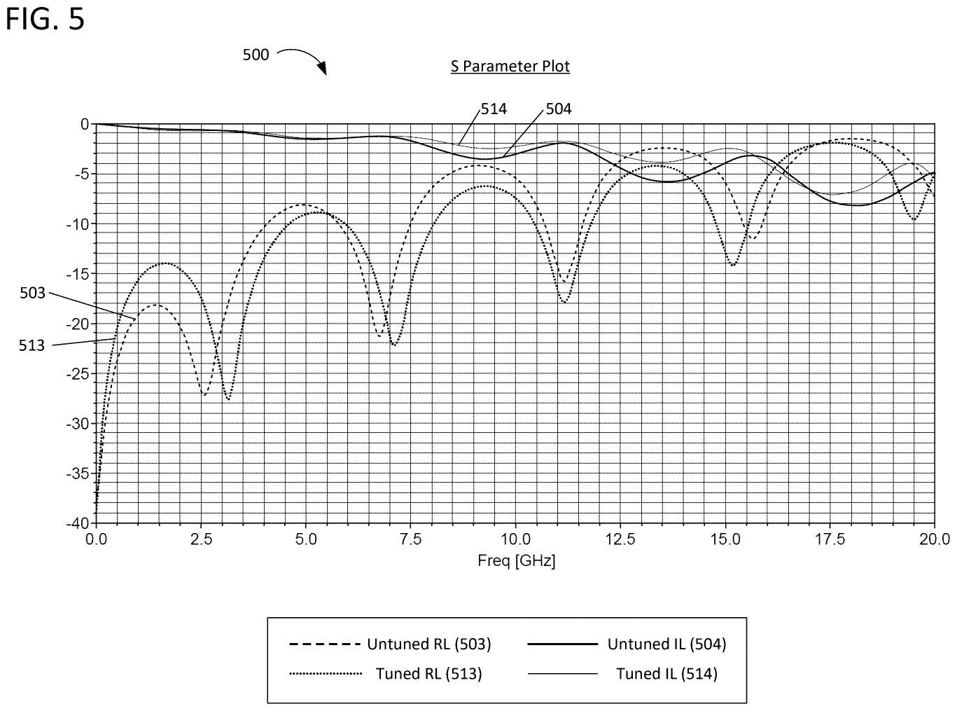

FIG. 5 illustrates graph 500 showing scattering (S) parameters (return loss and insertion loss) across frequencies for a die-to-die channel without tuned structures (lines 503 and 504) and a die-to-die channel with tuned structures (lines 513 and 514). In specific embodiments, the channel without tuned structures may have unoptimized tuning structures or may not have any tuning structures. The tuned design has better performance in both return loss (RL) and insertion loss (IL) than the untuned design. Additionally, the improvement of the tuned design in channel bandwidth shows significant increases in eye height (minEH) and eye width (minEW).

The tuning structures can be shaped to improve the radio frequency characteristics of the chip-to-chip connections by providing impedance matching. Tuning structures can introduce or improve impedance matching to minimize loss and crosstalk on the chip-to-chip or die-to-die connections. Analyzing the height and width of a data eye for a signal transmitted on the chip-to-chip or die-to-die connection can be used as a proxy for measuring the performance of the connection in maintaining signal integrity for signals transmitted using the connection.

The tuning structure can provide impedance matching, through the capacitance introduced between the conductive material of the tuning structure and the insulative material of the substrate and the resistance introduced by extending the length of the connection to the main trace. In specific embodiments, the size of the tuning structures can be selected to maximize an eye height and an eye width of the chip-to-chip or die-to-die connection. For example, two tuning structures on either side of a connection can be rectangular and share a height and width. The height and the width can increase an eye height and an eye width of the chip-to-chip connection as compared to the same chip-to-chip or die-to-die connection without the two tuning structures and with the main trace directly coupling the two escape region connections.

In specific embodiments of the invention, tuning a chip-to-chip connection can be conducted through an iterative process, subject to certain constraints, which seeks to minimize radiofrequency (RF) loss on the chip-to-chip connections. S-parameters define reflections and transfers of energy in an RF system. The process of minimizing RF loss may use the data eye height and eye width as two key metrics to maximize while configuring the lengths of the escape area connections, and shape (e.g., the lengths and widths) of the tuning structures.

The tuning structures may have a variety of geometries. In the example of FIG. 5, optimizing the tuning structures based on design rules, the tunning structures may have an escape region connection length (L0) of 1.35 mm, a tuning structure length (L1) of 1.05 mm, a tuning structure width (W1) of 40 μm, and a main trace width (W2) of 27 μm.

In specific embodiments, the tuning structures can be sheets of conductive material formed on an insulative substrate and having various top-down shapes. The surface area of the top-down shape can define a capacitance provided by the tuning structure. The conductive material can be the conductive material that is used to form the main trace or the edge region connection. The distance of the path across the surface area from the edge structure to the main trace and the width of that path can define a resistance provided by the tuning structure. In specific embodiments, the tuning structures can be tuning blocks having quadrilateral top-down shapes formed in a sheet on an insulative substrate.

The tuned channel (e.g., trace) may have improved properties compared to the untuned channel (e.g., that has unoptimized tuning structures or does not have any tuning structures). For example, tuned the channel of FIG. 5 may have improved impedance matching, larger bandwidth, less signal reflection, less return loss, less insertion loss, improved crosstalk, improved data eye height, and improved data eye width compared to the untuned channel.

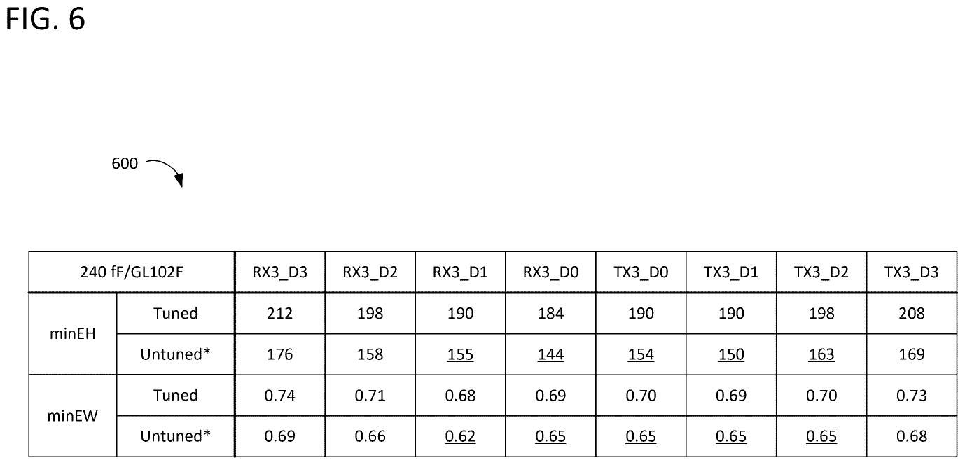

FIG. 6 shows table 600 of a simulation of minimum eye heights (minEH) and minimum eye widths (minEW) for various datalines (RX3_D3, RX3_D2, RX3_D1, RX3_D0, TX3_D0, TX3_D1, TX3_D2, TX3_D3) in a system. As there are multiple datalines (4RX, 4TX, and 2 CLK pair), crosstalk effects are included in the simulation. In this example, the I/O pad capacitance is 240 fF and the channels are made of GL102F.

Channels may be subject to certain specification requirements. In the example of table 600, the underlined values do not meet the requirements. The minimum eye height values for several untuned channels (e.g., channels without tuning structures or with unoptimized tuning structures) fall below the requirements: RX1_D1 (155), RX3_D0 (144), TX3_D0 (154), TX3_D1 (150), and TX3_D2 (163). However, in the example of table 600, these same datalines meet or exceed minimum eye height requirements when they are tuned (e.g., the channels have tuning structures, the tuning structures are optimized): RX1_D1 (190), RX3_D0 (184), TX3_D0 (190), TX3_D1 (190), and TX3_D2 (198).

Similarly, the minimum eye width values for several untuned channels (e.g., channels without tuning structures or with unoptimized tuning structures) fall below the requirements: RX1_D1 (0.62), RX3_D0 (0.65), TX3_D0 (0.65), TX3_D1 (0.65), and TX3_D2 (0.65). However, in the example of table 600, these same datalines meet or exceed minimum eye width requirements when they are tuned (e.g., the channels have tuning structures, the tuning structures are optimized): RX1_D1 (0.68), RX3_D0 (0.96), TX3_D0 (0.70), TX3_D1 (0.69), and TX3_D2 (0.70).

The tuning structures do not have a negative impact on crosstalk. The eye opening (eye height and eye width) is improved significantly after tunning even with all the aggressors included. Accordingly, the crosstalk from the aggressors for the tuned design does not have negative impact on the eye opening.

The channel with tuned tuning structures has improved properties compared to the channel without tuned tuning structures. For example, the tuned channel may have improved impedance matching, larger bandwidth, less signal reflection, less return loss, less insertion loss, improved crosstalk, improved data eye height, and improved data eye width. The tuned channel may achieve these benefits with minimal increase to the cost of the design, as tuning structures may be formed of the single material and using the same processing steps as a main trace and escape region connections of the channel. The geometry of the optimized tuning structures may be found via simulations.

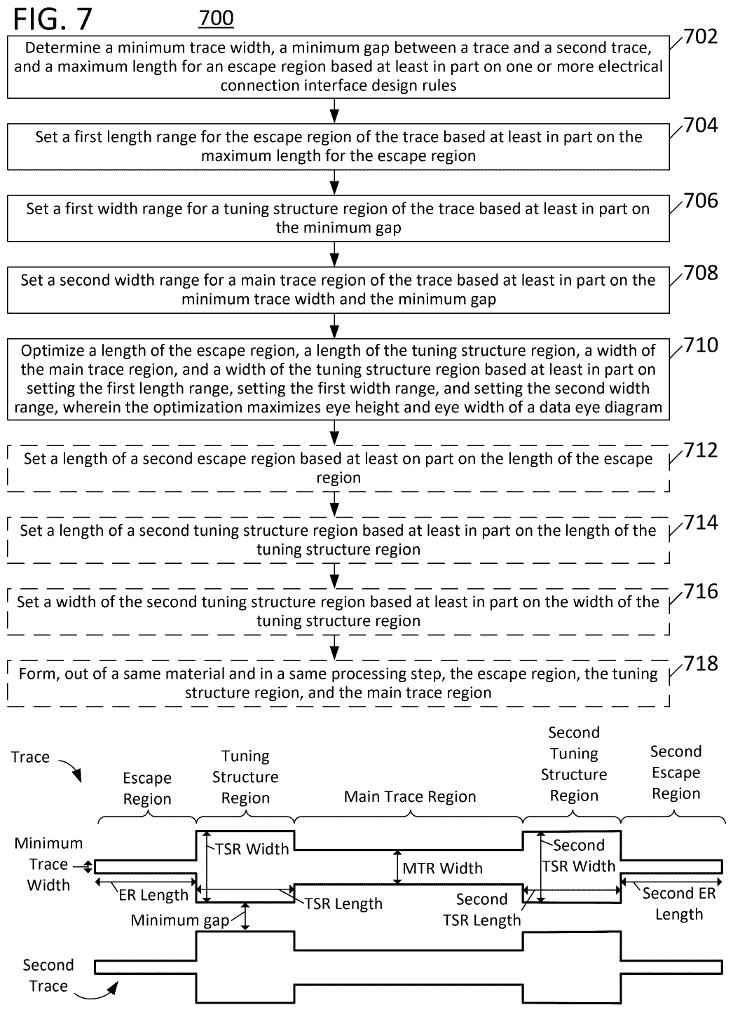

FIG. 7 illustrates an example of method 700 for tuning an electrical connection interface. In specific embodiments, method 700 may be performed using one or more processors. In specific embodiments, the electrical connection interface may include a first die, a first die connection (e.g., a contact), a first tuning structure, a first escape region (e.g., escape region connection), a second die, a second die connection, a second die tuning structure, a second escape region, and a main trace. The electrical connection interface may be on a printed circuit board (PCB). The electrical connection interface may include or be a part of an I/O pad or other high speed link. In specific embodiments, steps of method 700, or portions of steps, may be omitted, duplicated, rearranged, or otherwise deviate from the method as shown.

At step 702, a minimum trace width, a minimum gap (e.g., spacing) between a trace and a second trace, and a maximum length for an escape region (e.g., an escape region connection) may be determined based on one or more electrical connection interface design rules. In specific embodiments, there may be more than one trace. The second trace may or may not include a tuning structure region. In other embodiments, the second trace may only be hypothetical. In specific embodiments, the minimum gap between the trace and the second trace may set a maximum width of a tuning structure.

At step 704, a first length for the escape region of the trace may be set based on the maximum length for the escape region (e.g., determined at step 702).

At step 706, a first width range for a tuning structure region of the trace may be set based on the minimum gap between the trace and the second trace (e.g., both minimums determined at step 702).

At step 708, a second width range for a main trace region of the trace may be set based on the minimum trace width and the minimum gap between the trace and the second trace (e.g., both minimums determined at step 702).

At step 710, a length of the escape region, a length of the tuning structure region, a width of the main trace region, and a width of the tuning structure may be optimized. These lengths and widths may be optimized based on setting the first length range for the escape region (e.g., at step 704), setting the first width range for the tuning structure region (e.g., at step 706), and setting the second width range for the main trace region (e.g., at step 708). Optimizing the widths and lengths may be based on maximizing an eye height and an eye width of an associated data eye diagram. Optimization may be performed in a variety of ways. In specific embodiments, optimization may include a parametric sweep (e.g., a series of simulations). In specific embodiments, optimization may include an iterative process subject to constraints. In specific embodiments, optimization seeks to minimize RF loss on the connections (e.g., chip-to-chip, die-to-die).

In specific embodiments, at step 712, a length of a second escape region may be set based on the length of the escape region (e.g., optimized at step 710).

In specific embodiments, at step 714, a length of a second tuning structure region may be set based at least in part on the length of the tuning structure (e.g., optimized at step 710).

In specific embodiments, at step 716, a width of the second tuning structure region may be set based on the width of the tuning structure region (e.g., optimized at step 710). Although illustrated as part of the trace, in specific embodiments, the second tuning structure region and second escape region may be part of the second trace or a different trace.

In specific embodiments, at step 718, the escape region, the tuning structure region, and the main trace region may be formed out of the single material and in the same processing step. In specific embodiments, the escape region, the tuning structure region, and the main trace region may be formed based on the optimized dimensions of step 710. In specific embodiments, the second escape region and the second tuning structure may also be formed out of the single material (and in the same processing step) as the escape region, the tuning structure region, and the main trace region.

Method 700 may be repeated for multiple traces. Some traces in a set of traces may have the same or similar dimensions. Other traces may have different dimensions. Some traces may not include tuning structure regions while others do. Some traces may not include escape regions while others do. Although illustrated as rectangular, tuning structure regions may be any shape while still connecting an escape region to a main trace region.

A trace with optimized tuning structures may have improved properties compared to a trace without tuning structures or with suboptimal tuning structures. For example, the trace with optimized tuning structures may have improved impedance matching, larger bandwidth, less signal reflection, less return loss, less insertion loss, improved crosstalk, improved data eye height, and improved data eye width. The trace with optimized tuning structures may achieve these benefits with minimal increase to the cost of the design, as the tuning structures may be formed of the single material and using the same processing steps as the main trace and escape region connections of the trace.

While the specification has been described in detail with respect to specific embodiments of the invention, it will be appreciated that those skilled in the art, upon attaining an understanding of the foregoing, may readily conceive of alterations to, variations of, and equivalents to these embodiments. Although examples in the disclosure were generally directed to die-to-die connection, the same approaches could be utilized to improve the performance of any form of physical high-speed link. These and other modifications and variations to the present invention may be practiced by those skilled in the art, without departing from the scope of the present invention, which is more particularly set forth in the appended claims.

What is claimed is:

1. An electrical connection interface comprising:
a first die connection for a first die;
a first tuning block;
a first escape region connection coupling the first die connection to the first tuning block;
a second die connection for a second die;
a second tuning block;
a second escape region connection coupling the second die connection to the second tuning block; and
a main trace coupling the first tuning block to the second tuning block.

2. The electrical connection interface of claim 1, wherein:
the first tuning block and the second tuning block are wider than the main trace;
the first escape region connection is narrower than the main trace; and
the first tuning block, the second tuning block, the main trace, and the first escape region connection are formed by a single material.

3. The electrical connection interface of claim 1, wherein:
the first tuning block and the second tuning block share a width and a length; and
the width and the length increase an eye height and an eye width of the electrical connection interface as compared to a same electrical connection: (i) without the first tuning block and the second tuning block; and (ii) with the main trace coupling the first escape region connection to the second escape region connection.

4. The electrical connection interface of claim 1, wherein:
the first escape region connection and the second escape region connection are longer than 1 millimeter;
the first tuning block and the second tuning block are thicker than 30 microns and longer than 1 millimeter; and
the main trace, the first escape region connection, and the second escape region connection are narrower than 1 millimeter.

5. The electrical connection interface of claim 1, wherein:
the main trace, the escape region connections, the first tuning block, and the second tuning block are all formed by a wire material on an insulative substrate; and
the first die connection and the second die connection are one of:
solder bumps and die pads.

6. The electrical connection interface of claim 1, further comprising:
a pair of adjacent die connections for the first die, wherein the pair of adjacent die connections are adjacent to the first die connection; and
a pair of adjacent tuning blocks, wherein the pair of adjacent tuning blocks are coupled to the pair of adjacent die connections;
wherein: (i) the first escape region connection has a minimum width as set by an electrical connection interface design rule and a length less than a maximum allowed by the electrical connection interface design rule; and (ii) the first tuning block has a maximum possible width set by a required minimum spacing between the first tuning block and the pair of adjacent tuning blocks as set by the electrical connection interface design rule.

7. The electrical connection interface of claim 1, wherein:
the first tuning block, the second tuning block, the main trace, and the escape region connections are all formed of a metal trace material on an insulative substrate.

8. The electrical connection interface of claim 1, wherein:
an impedance of the first tuning block and the first escape region connection match an impedance of the main trace.

9. An electrical connection interface comprising:
a first die connection for a first die;
a first tuning structure;
a first escape region connection coupling the first die connection to the first tuning structure;
a second die connection for a second die;
a second tuning structure;
a second escape region connection coupling the second die connection to the second tuning structure; and
a main trace coupling the first tuning structure to the second tuning structure;
wherein the main trace, the first tuning structure, the second tuning structure are all formed of a single material.

10. The electrical connection interface of claim 9, wherein:
the first tuning structure and the second tuning structure are wider than the main trace;
the first escape region connection is narrower than the main trace; and
the main trace, the first escape region connection, and the second escape region connection are formed by the single material.

11. The electrical connection interface of claim 9, wherein:
the first tuning structure has a width and a length;
the second tuning structure has the width and the length; and
the width and the length increase an eye height and an eye width of the electrical connection interface as compared to a same electrical connection: (i) without the first tuning structure and the second tuning structure; and (ii) with the main trace coupling the first escape region connection to the second escape region connection.

12. The electrical connection interface of claim 9, wherein:
the first escape region connection and the second escape region connection are longer than 1 millimeter;
the first tuning structure and the second tuning structure are thicker than 30 microns and longer than 1 millimeter; and
the main trace, the first escape region connection, and the second escape region connection are narrower than 1 millimeter.

13. The electrical connection interface of claim 9, wherein:
the single material is a wire material;
the main trace, the first escape region connection, the second escape region connection, the first tuning structure, and the second tuning structure are all formed on an insulative substrate; and
the first die connection and the second die connection are one of:
solder bumps and die pads.

14. The electrical connection interface of claim 9, further comprising:
a pair of adjacent die connections for the first die, wherein the pair of adjacent die connections are adjacent to the first die connection; and
a pair of adjacent tuning structures, wherein the pair of adjacent tuning structures are coupled to the pair of adjacent die connections;
wherein: (i) the first escape region connection has a first width greater than or equal to a minimum width as set by an electrical connection interface design rule and a length less than or equal to a maximum length allowed by the electrical connection interface design rule; and (ii) the first tuning structure has a second width less than or equal to a maximum width set by a required minimum spacing between the first tuning structure and the pair of adjacent tuning structures as set by the electrical connection interface design rule.

15. The electrical connection interface of claim 9, wherein:
the first tuning structure, the second tuning structure, the main trace, the first escape region connection, and the second escape region connection are all formed of a metal trace material on an insulative substrate.

16. The electrical connection interface of claim 9, wherein:
an impedance of the first tuning structure and the first escape region connection match an impedance of the main trace.

17. A method for tuning an electrical connection interface,
comprising:
determining a minimum trace width, a minimum gap between a trace and a second trace, and a maximum length for an escape region based at least in part on one or more electrical connection interface design rules;
setting a first length range for the escape region of the trace based at least in part on the maximum length for the escape region;
setting a first width range for a tuning structure region of the trace based at least in part on the minimum gap;
setting a second width range for a main trace region of the trace based at least in part on the minimum trace width and the minimum gap; and
optimizing a length of the escape region, a length of the tuning structure region, a width of the main trace region, and a width of the tuning structure region based at least in part on setting the first length range, setting the first width range, and setting the second width range, wherein the optimization maximizes eye height and eye width of a data eye diagram.

18. The method of claim 17, wherein:
a width of the escape region is the minimum trace width.

19. The method of claim 17, further comprising:
forming, out of a single material and in a same processing step, the escape region, the tuning structure region, and the main trace region.

20. The method of claim 17, further comprising:
setting a length of a second escape region based at least on part on the length of the escape region;
setting a length of a second tuning structure region based at least in part on the length of the tuning structure region; and
setting a width of the second tuning structure region based at least in part on the width of the tuning structure region.
